(19) United States
(12) Patent Application Publication
(10) Pub. No.: US 2012/0244668 A1
(43) Pub. Date: Sep. 27, 2012

(54) SEMICONDUCTOR DEVICES WITH LAYOUT CONTROLLED CHANNEL AND ASSOCIATED PROCESSES OF MANUFACTURING

(76) Inventor: Jeesung Jung, San Jose, CA (US)

(21) Appl. No.: 13/072,569

(22) Filed: Mar. 25, 2011

(51) Int. Cl. H01L 21/337

(52) U.S. Cl. 438/192; 257/E21.445

(57) ABSTRACT

The present technology is directed generally to processes of forming semiconductor devices (e.g., JFET devices). The semiconductor device comprises a gate region, a source region, a drain region and a channel region having a channel size. The channel size is controlled by adjusting a layout width of the gate region.

### TECHNICAL FIELD

The present technology generally relates to semiconductor devices such as junction field effect transistor (“JFET”) devices.

### BACKGROUND

JFET is a type of transistor with a conducting behavior controlled by a gate voltage. FIG. 1A shows a conventional N-type JFET device 100. The JFET device 100 has three terminals: a source terminal S, a drain terminal D, and a gate terminal G. The drain-source resistance R_{DS} between the source S and the drain D is controlled by a gate voltage. The JFET device 100 comprises a P-type substrate 11, an Nwell 12 in the substrate 11, and a Pwell gate region 13 in the Nwell 12. The source region 121 and the drain region 123 are in the Nwell 12 at the two sides of the gate region 13. The channel 122 is in the Nwell 12 and between the gate region 13 and the bottom substrate 11. The depth d2 of the channel 122 is related to a threshold voltage V_{TH} of pinching off the channel and its current carrying capability.

When the gate terminal G is floating (i.e., no applied external voltage), the undepleted N-type channel 122 with a channel size d2 is shown in FIG. 1A. When the source-gate voltage V_{SG} increases, as shown in FIG. 1B, a depletion region 1 expands from the gate region 13 into the Nwell 12. Also, another depletion region 2 near the substrate 11 may expand into the Nwell 12 due to the voltage biasing. As a result, the effective width of the channel 122 decreases and its channel resistance R_{DS} increases. When V_{SG} is high enough and reaches the pinch-off threshold voltage V_{TH}, the channel 122 is pinched off and the conduction path disappears as shown in FIG. 1C.

Referring back to FIG. 1A, given a certain channel doping concentration, the higher the channel size d2, the higher the threshold voltage V_{TH}, and the higher the current carrying capability of the JFET device 100. The channel size generally refers to a size of the conduction path when the gate region 13, the drain region 121, the source region 123, and the substrate 11 are floated (i.e., without voltage biasing).

Different applications require different levels of threshold voltage V_{TH} and current carrying capability. Thus, the size of the channel 122 d2 needs to be adjusted according to the specific requirement. In conventional integration processes, the size of the channel 122 d2 is determined by controlling an ion-implantation dosage, energy, tilt during formation of the Pwell 13, as well as using annealing processes after the formation of the Pwell 13. The channel size d2=d0−d1, where d0 is the depth of the Nwell 12 and d1 is the depth of the Pwell gate region.

When low current carrying capability and low V_{TH} are desired, the implantation dosage, energy, and thermal budget of annealing for forming the Pwell 13 are increased and accordingly d1 is large and d2 is small. And when high current carrying capability and high V_{TH} are desired, the implantation dosage, energy, and thermal budget of annealing for forming the Pwell 13 are decreased and accordingly d1 decreases and the channel size d2 increases.

In an integration process, if multiple Pwells are fabricated with different implantation depths, additional masks are adopted to define the specific depth because any change in the implantation dosage, energy, and thermal budget of annealing may affect the other structures. Using multiple masks adds to fabrication costs. Accordingly, several improvements to efficiently and cost effectively produce JFET devices may be desirable.

### BRIEF DESCRIPTION OF THE DRAWINGS

FIGS. 1A-1C schematically illustrate a conventional JFET device under certain operating conditions.

FIG. 2 shows a sectional view of a semiconductor device undergoing ion-implantation according to embodiments of the present technology.

FIG. 3 shows a sectional view of a semiconductor device having a JFET device according to embodiments of the present technology.

FIG. 4 shows a semiconductor device comprising a plurality of JFET devices according to additional embodiments of the present technology.

FIGS. 5A-5E illustrate a process of manufacturing a JFET device according to embodiments of the present technology.

FIGS. 6A-6G illustrate another process of manufacturing a JFET device according to additional embodiments of the present technology.

FIGS. 7A-7D illustrate a process of manufacturing an N-type JFET device according to embodiments of the present technology.

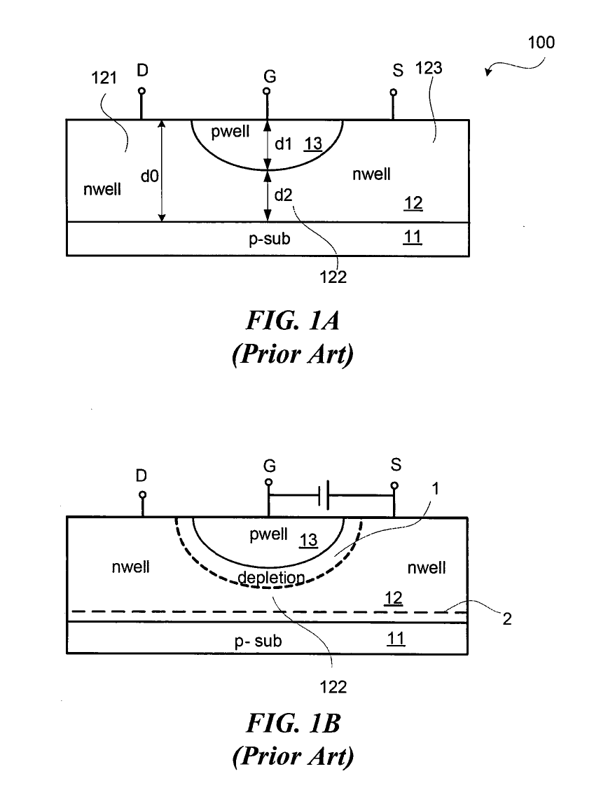

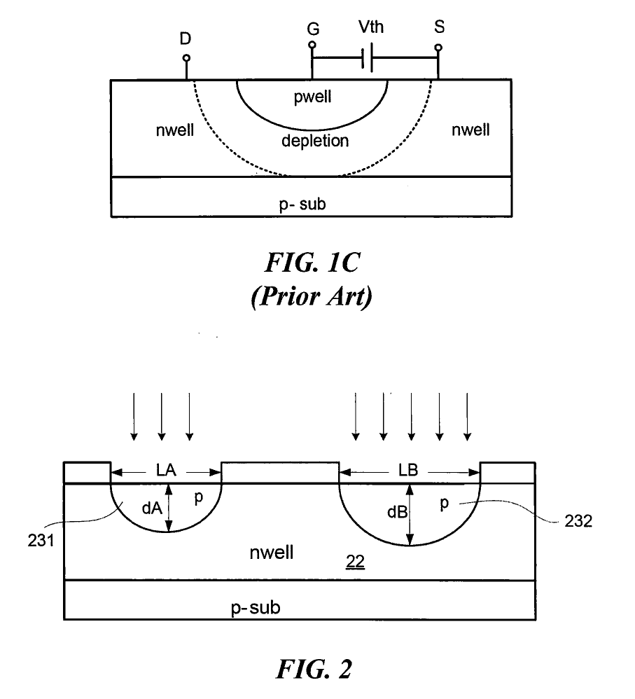

### DETAILED DESCRIPTION

Various embodiments of semiconductor devices and processs of manufacturing are described below. For example, in one embodiment, a process of forming a JFET device comprises forming a gate region, forming a channel region having a channel size, forming a source region and forming a drain region. The channel size is controlled by adjusting a width of the gate region. Many of the details, dimensions, angles, shapes, and other features shown in the figures are merely illustrative of particular embodiments of the technology. A person skilled in the relevant art will also understand that the technology may have additional embodiments, and that the technology may be practiced without several of the details of the embodiments described below with reference to FIGS. 2-7D.

In the following description, A having a “positive relationship” with B generally refers to a condition under which when B increases, A increases in response; or when B decreases, A decreases as well. A having a “negative relationship” with B generally refers to a condition under which A and B are in trade-off relationship. For example, when B increases, A decreases in response; or when B decreases, A increases in response.

FIG. 2 shows a sectional view of a semiconductor device undergoing ion-implantation according to embodiments of the present technology. Without being bound by theory, it is believed that with a particular implantation ion dosage, implantation energy, tilt, annealing conditions, and/or other implantation conditions, the final depth of an implanted well has a positive relationship with the width of a corresponding mask opening. Thus, the wider the mask opening, the deeper the implanted well. For example, as shown in FIG. 2, two Pwells 231 and 232 are formed in the Nwell 22 under generally similar implantation conditions. The Pwell 231 is formed with a mask opening width of LA, and the Pwell 232 is formed with a mask opening width of LB wider than LA. Thus, the implantation depth dA of the Pwell 231 is shallower than the implantation depth dB of the Pwell 232. Accordingly, it has been recognized that a desired channel size in a JFET device can be controlled by adjusting a width of a corresponding mask opening, also referred to a layout width of a corresponding gate region of the JFET device. For example, a channel size of an N-type JFET is proportional to a thickness of its Nwell minus a depth of its gate region.

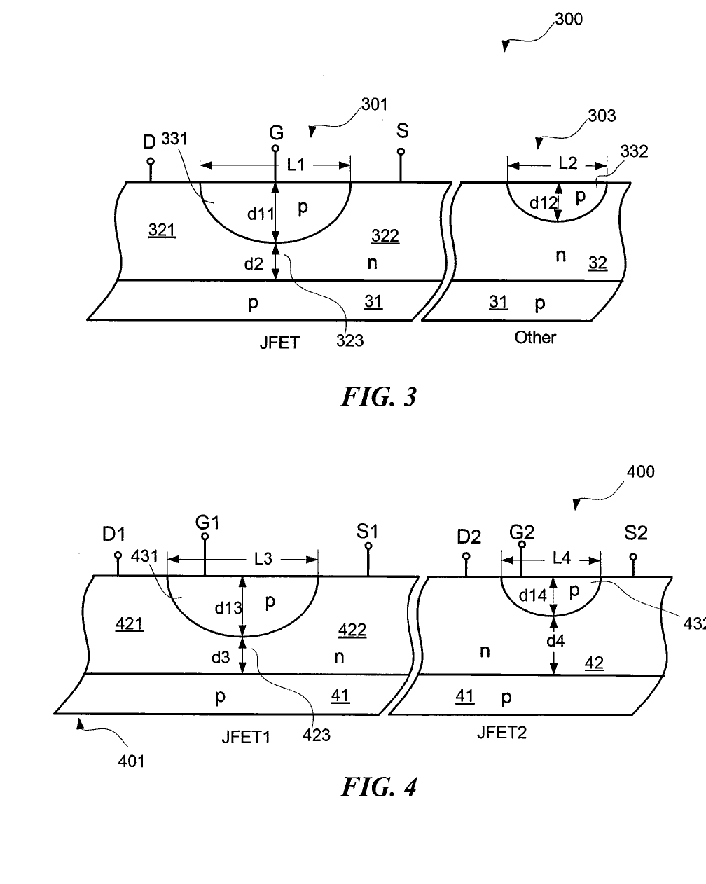

FIG. 3 shows a sectional view of a semiconductor device 300 according to embodiments of the present technology. The semiconductor device 300 comprises a JFET region 301 in which one or more JFET devices may be fabricated. In the illustrated embodiment, the JFET region 301 comprises a P-type substrate material. In other embodiments, the substrate 31 can comprise an N-type substrate material and/or other suitable types of semiconductor material. Even though only one JFET region 301 is shown in FIG. 3, in other embodiments, a plurality of similar or different JFET regions 301 may be electrically connected in parallel.

The JFET region 301 further comprises a drain region 321, a gate region 331, a source region 322, and a channel region 323 in the substrate 31. In the illustrated embodiment in FIG. 3, the JFET device includes an N-type JFET device. Thus, the drain region 321, the source region 322, and the channel region 323 may be doped with N-type dopants while the gate region 331 and the substrate 31 are doped with P-type dopants. In another embodiment, the JFET device includes a P-type JFET device. Thus, the drain region 321, the source region 322, and the channel region 323 may be doped with P-type dopants while the gate region 331 and the substrate 31 are doped with N-type dopants. The drain region 321 and the source region 322 are located at the sides of the gate region 331. The channel region 323 is vertically between the gate region 331 and the substrate 31 and laterally between the source region 322 and the drain region 321. The drain region 321, the source region 322, and the gate region 331 are coupled to external circuitries (not shown) through a drain electrode D, a source electrode S, and a gate electrode G, respectively.

The channel region 323 provides a conduction path between the source region 322 and the drain region 321. The conduction current is controlled by the gate voltage. When a positive source-gate voltage V_{SG} is applied, the surface of the channel 323 near the gate region 331 is depleted and the resistance between the drain and the source R_{DS} increases. When V_{SG} reaches a threshold voltage V_{TH}, the current path is pinched off.

The channel size d2 of the channel region 322 at V_{SG}=0 and V_{DS}=0 is believed to influence the threshold voltage V_{TH} and the current carrying capability of the JFET region 301. With a particular doping concentration in the Nwell, the pinch-off threshold voltage V_{TH} is believed to be related to the channel size d2. It is believed that the wider the channel opening 322, the higher the threshold voltage V_{TH}. The channel resistance (or the current carrying capability) is also believed to be related to the channel size d2. It is believed that when the channel size d2 increases, the channel resistance R_{DS} decreases correspondingly. Thus, the current carrying capability increases.

In certain embodiments, the channel size d2 may be controlled by adjusting the layout width L1 of the gate region 331. As discussed above, adjusting the layout width L1 of the gate region 331 affects the gate depth d11, which in turn affects the channel size d2. Thus, when L1 increases, d11 increases, and d2 decreases. On the other hand, when L1 decreases, d11 decreases, and the channel size d2 increases.

As shown in FIG. 3, the semiconductor device 300 may further comprise at least one Pwell 332 in a peripheral region 303 of the N-type layer 32 while the N-type layer 32 is fabricated in the semiconductor substrate 31. The Pwell 332 and the Pwell gate region 331 in the JFET region 301 can be fabricated with a single mask in one process operation. In one embodiment, the Pwell 332 can be a gate region of an additional JFET region (not shown). In other embodiments, the Pwell 332 may have other functions. For example, the PweII 332 can be a base region of an N-type bipolar junction transistor (“BJT”).

The depth of the Pwell 332 may also be controlled by adjusting its layout width as discussed above with reference to FIG. 2. As seen in FIG. 3, the width L1 of the PweII 331 is wider than the width L2 of the Pwell 332, while the depth d11 of the gate region 331 of the JFET device is deeper than the depth d12 of the Pwell 332. In other examples, the Pwells 331 and 332 may have other relationships in gate width, gate region, and/or other aspects.

FIG. 4 shows a semiconductor device 400 with a plurality of JFET devices according to embodiments of the present technology. As shown in FIG. 4, the semiconductor device 400 comprises a first JFET device JFET1 and a second JFET device JFET2 integrated into a single semiconductor substrate 401. Each JFET device comprises a drain, a source, a gate and a channel. The gate depths d13 and d14 of JFET1 and JFET2 are controlled by adjusting the layout width L3 and L4 respectively.

The gate depth of each of the JFET devices JFET1 and JFET2 has a positive relationship with its width. Thus, the channel size d3 of JFET1 is controlled by adjusting the layout width L3 and the channel size d4 of JFET2 is controlled by adjusting the layout width L4 with a negative relationship. The channel size d3 has a negative relationship with the channel resistance (drain-source resistance R_{DS}). Because the gate width L3 of JFET1 is wider than the gate width L4 of JFET2, the channel size d3 is smaller than d4 and the drain-source resistance of JFET1 is higher than the drain-source resistance of JFET2. The pinch-off threshold voltage and current carrying capability of JFET1 at a given bias conditions are lower than that of JFET2.

Even though the foregoing embodiments relate to N-type JFET devices, in other embodiments, P-type JFET devices with the opposite doping types may also be produced according to embodiments of the present technology. In one embodiment, a first doping type is N doping type (e.g., doped with phosphor or arsenic), and a second doping type is P doping type (e.g., doped with boron, aluminum, or gallium). In another embodiment, a first doping type is P doping type, and the second doping type is N doping type.

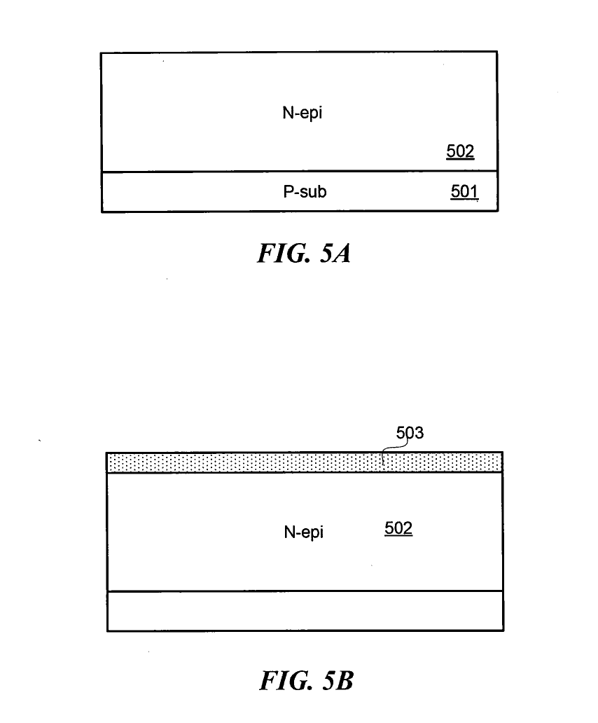

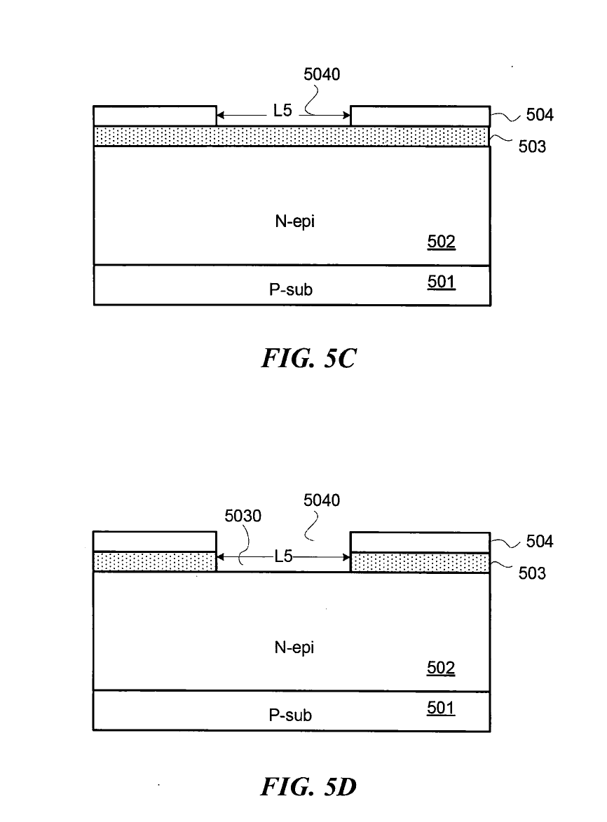

FIGS. 5A-5E illustrate a process of manufacturing a JFET device according to embodiments of the present technology. In an initial stage, an N-type epitaxial layer is grown on a substrate. A photoresist layer is then deposited onto the epitaxial layer. Then, a opening is formed on the photoresist layer, and the opening width is selected based on a target channel size and implantation/annealing conditions. Next, P-type dopants are implanted into the opening and diffused by thermal annealing to form a gate region. Subsequently, an N+ source contact region at one side of the gate region and another N+ drain contact region at the other side of the gate region may be formed with a single mask.

The foregoing process are illustrated in detail with reference to FIGS. 5A-5E. Referring to FIG. 5A, an N-type epitaxial layer 502 is formed on a P-type substrate 501. In one embodiment, after forming the epitaxial layer 502, ion-implantation is performed, and N-type dopants are implanted into the epitaxial layer 502 to achieve a target N-type doping concentration.

FIGS. 5B-5D illustrate a photolithography process of forming a gate region of the JFET device and controlling a channel size of the JFET device. As shown in FIG. 5B, a photoresist layer 503 is deposited onto the N-type layer 502. As shown in FIG. 5C, a mask 504 with an opening 5040 is placed above the photoresist layer 503. The width L5 of the mask opening 5040 is selected based on a target performance of the JFET device (e.g., a threshold voltage V_{TH}, a drain-source resistance, and/or other suitable parameters of the JFET device).

In one embodiment, when the doping concentrations are changed due to corresponding process changes, the target performance of the JFET device can be achieved by adjusting the channel size. Since the depth of the gate can be adjusted by the width of the mask opening 5040 and the depth of the N-type epitaxial layer 502 has a predetermined thickness, the channel size can also be controlled by the mask opening 5040. If high drain-source resistance and/or low threshold voltage is desired, the channel opening can be small, thus the gate region is controlled to be deep and the opening width L5 can be wide. On the other hand, if low drain-source resistance and/or high threshold voltage is required, the channel opening can be wide and the opening width L5 can to be narrow.

In another embodiment, when the doping concentration is changed due to process changes, the target performance of a JFET device can be achieved by adjusting a layout width of its gate region. For example, if the doping concentration of the channel region is increased due to other devices, the channel opening may be adjusted narrower to maintain the JFET device's characteristic. Accordingly, the mask opening 5040 can be adjusted wider to maintain the predetermined characteristic. On the other hand, if the doping concentration of the channel region is decreased, the mask opening 5040 for the gate region may be adjusted narrower. As shown in FIG. 5D, the photoresist layer 503 is patterned to have an opening 5030 with the same width L5 as the mask opening 5040.

In FIG. 5E, P-type dopants are ion-implanted into the opening 5030 of the photoresist layer 503 under suitable implantation conditions and an annealing process is performed under suitable thermal recipes to form the gate region 53 of the JFET device. In certain embodiments, the implantation conditions may also be used to form other Pwell(s). The implantation conditions may include implantation ion dosage, energy, tilt, and other suitable implantation conditions. As described with reference to FIG. 2, the depth d15 of the gate region 53 has a positive relationship with its width L5. Thus, the size d5 of the channel 51 between the gate region and the substrate has a negative relationship with the width L5. The process can also include forming N+ source contact region/drain contact regions and/or other suitable process operations.

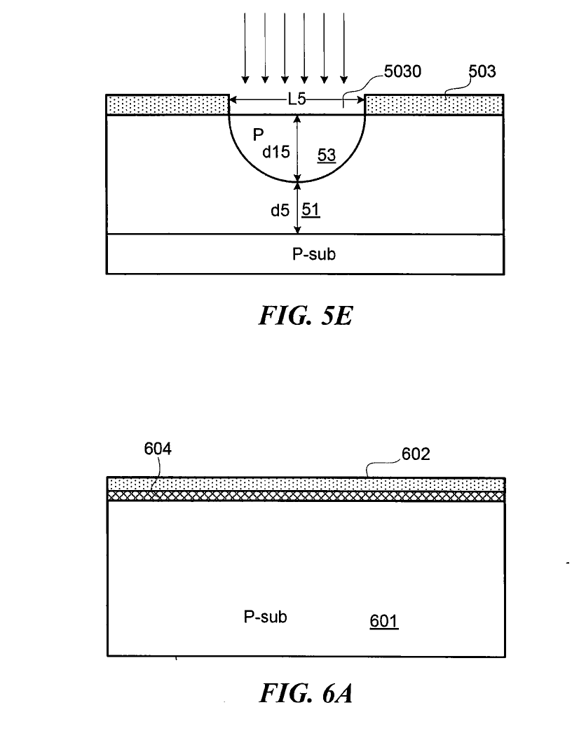

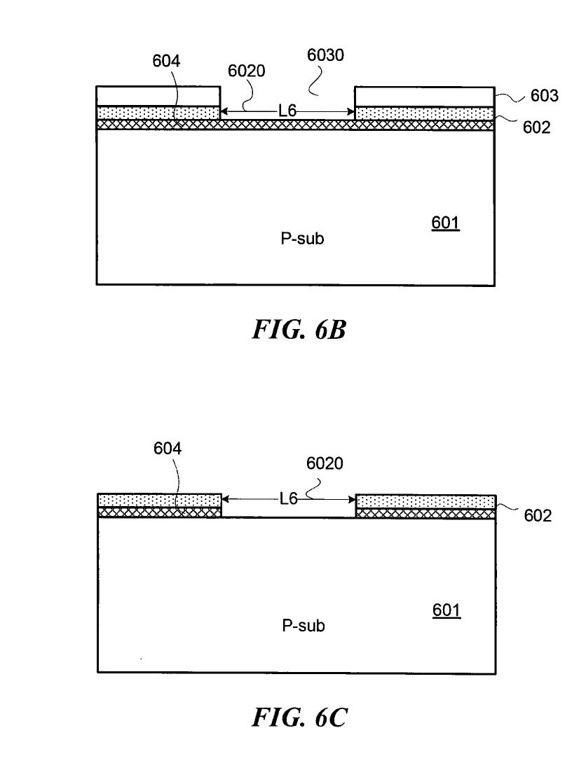

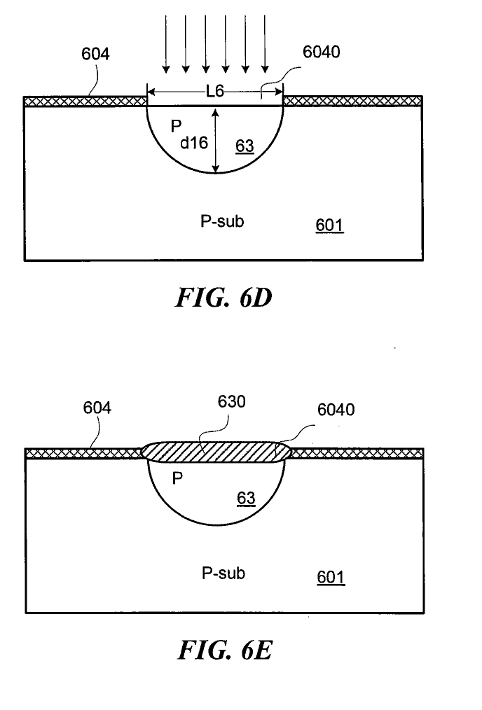

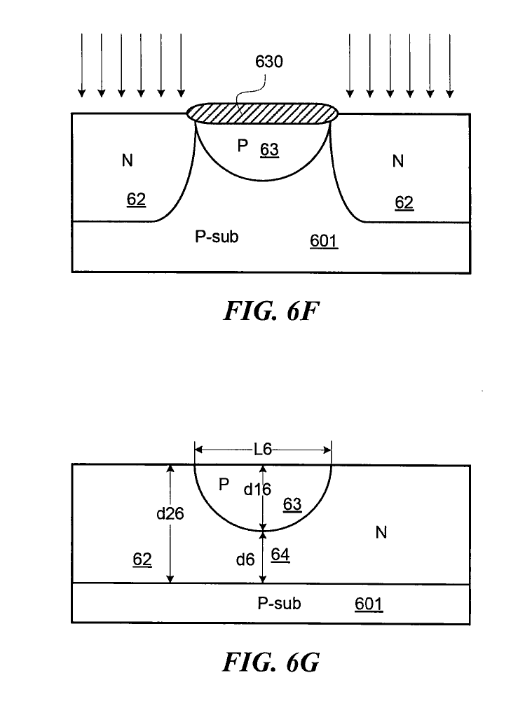

FIGS. 6A-6G illustrate another process of manufacturing a JFET device. In the illustrated embodiment, the P-type gate region of the JFET device is formed before the Nwell while the Nwell is formed using the Pwell oxide as a mask. With predetermined Nwell conditions, the channel size of the JFET device is controlled by the depth of the gate region, and accordingly is adjusted by the width of the gate region.

In FIG. 6A, a nitride layer 604 is deposited on a substrate 601. The substrate 601 may comprises an oxide layer (not shown) on the surface, and the nitride layer 604 is deposited on the oxide layer. In one embodiment, the substrate 601 may be lightly doped with P-type dopants. The nitride layer 604 can be formed by chemical vapor deposition (CVD) and/or other suitable deposition techniques. Then a photoresist layer 602 is placed onto the nitride layer 604.

In FIG. 6B, a photolithography process is illustrated, which is generally similar to that shown in FIGS. 5B-5D. First, a mask 603 with an opening 6030 is placed onto the photoresist layer 602. The width L6 of the mask opening 6030 is selected to meet the performance requirement of the JFET or the channel size which has a negative relationship with the gate depth d16 (FIG. 6D), and thus the width L6 also has a negative relationship with the desired channel size. Then the photoresist layer 602 is patterned into the gate opening 6020.

As shown in FIG. 6C, the nitride layer 604 is etched through the gate opening 6020 of the photoresist layer 602 via plasma etching and/or other suitable etching techniques. The surface of the substrate 601 is then exposed having a width of L6. Then the photoresist layer 602 is removed, and the nitride layer 604 functions as a hard mask for forming the gate region.

As shown in FIG. 6D, P-type dopants are implanted into the opening 6040 of the nitride layer 604 to form the gate region 63 of the JFET device. Under predetermined implantation conditions including implantation ion dosage, energy, tilt and thermal annealing temperature, the gate depth d16 has a predetermined positive relationship with its width L6.

Then as shown in FIG. 6E, a Pwell oxidation process is performed in the nitride layer window 6040 and a Pwell oxide 630 is grown on the surface of the Pwell gate region 63. Then the nitride layer 604 is removed by chemical or mechanical techniques.

In FIG. 6F, the Pwell oxide 630 serves as a mask for the Nwell 62, and N-type dopants (e.g., phosphorous) are implanted and self-aligned to the edge of the Pwell oxide 630. After Nwell implantation, the Pwell oxide 630 is removed.

As shown in FIG. 6G, the Nwell 62 and Pwell 63 are annealed with predetermined thermal condition and Nwell 62 is diffused laterally under the Pwell gate region 63 and forms the channel 64. The Nwell 62 is implanted and driven in under predetermined thermal recipes considering all the circuits or components integrated in the semiconductor substrate 601 and leads to a predetermined depth d26. In certain embodiments, other component or semiconductor region (not shown) is integrated into the Nwell 62, thus it is not convenient to control the channel size of the JFET device by controlling the depth d26 of the Nwell 62. Meanwhile, under the predetermined thermal recipes, the side diffusion of the Pwell 63 is predetermined and the channel size can still be controlled by adjusting the layout width. The channel size d6 is proportional to d26-d16, and the gate depth d16 has a positive relationship with the width L6 of the gate mask. Thus, the channel size d6 can also be adjusted by the width L6 of the gate mask.

The processes shown in FIGS. 5A-5E and in FIGS. 6A-6G both control the channel size of the JFET device by adjusting the width of the gate mask. Thus when the JFET device is integrated with other circuit or components in a semiconductor substrate, the particular channel opening of the JFET device does not require additional masks as well as extra thermal treatment.

The processes described above control the channel opening of a JFET device by adjusting the layout width of a gate region. Yet in another embodiment, the channel opening of an N-type JFET device can be controlled by adjusting the layout of Nwell. And the channel opening of a P-type JFET device can be controlled by adjusting the layout of a Pwell.

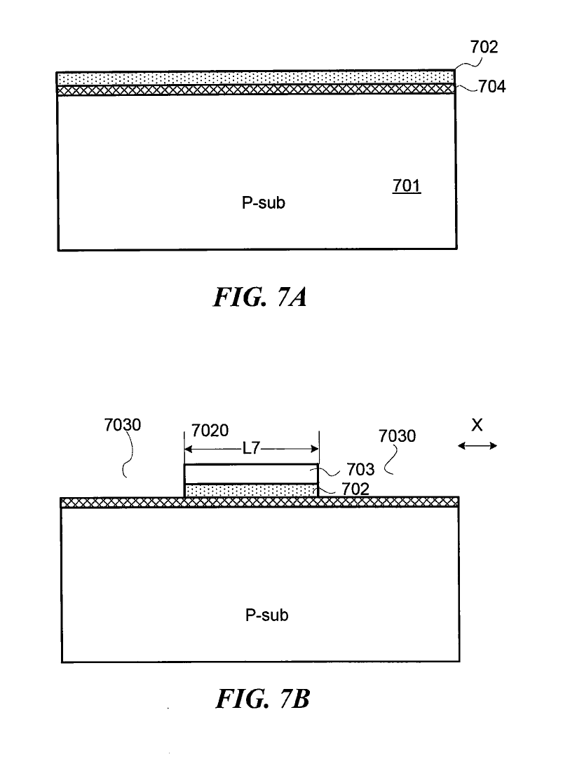

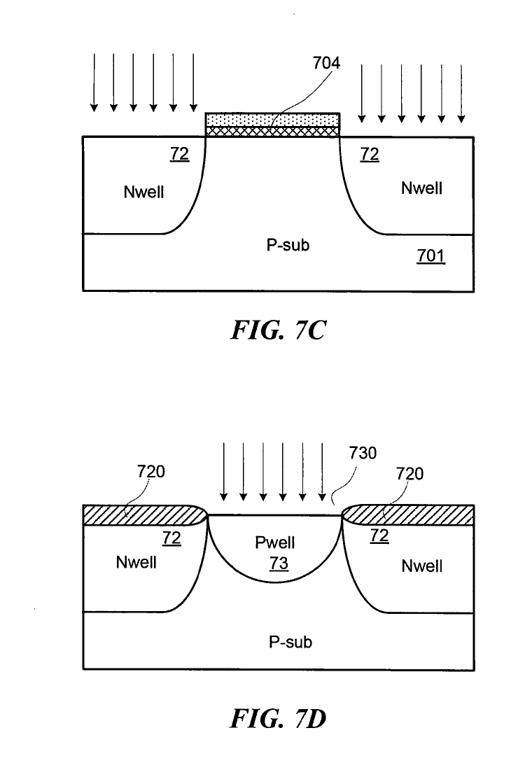

FIGS. 7A-7D illustrate a process of forming an N-type JFET device according to embodiments of the present technology. FIG. 7A shows forming a pad oxide layer (not shown) on a substrate 701 and then forming a nitride layer 704 on a substrate 701 and then forming a photoresist layer 702 onto the nitride layer 704. FIG. 7B shows a photolithography process. A mask 703 with mask openings 7030 is placed onto the photoresist layer 702, then the photoresist layer 702 is patterned. The mask 703 has a pattern with a width of L7 as a counter-part of the openings 7030.

As illustrated in FIG. 7C, the nitride layer 704 is etched and patterned into openings and N-type dopants are implanted into the openings to form Nwells 72. As shown in FIG. 7D, Nwell oxide 720 is grown on the surface of the Nwells 72, and the Nwell oxide 720 serves as a mask and P-type dopants are implanted into the opening 730 to form the gate region 73. The depth of the gate region 73 has a positive relationship with the gate opening 730. While the gate opening 730 is a counter-part of the mask openings 7030 (FIG. 7B), the gate depth has a predetermined positive relationship with the width L7.

Subsequently, Nwells 72 are diffused laterally under the Pwell gate region and forms the channel. Additional operations such as forming N+ drain contact regions, P+ gate contact regions may be performed thereafter to form the JFET device. Under controlled thermal recipes, the depth of the Nwell under the gate has a certain value and the channel size can be adjusted by the width of the gate region and accordingly adjusted by the layout width of the Nwells 72.

From the foregoing, it will be appreciated that specific embodiments of the technology have been described herein for purposes of illustration, but that various modifications may be made without deviating from the disclosed technology. For example, though the semiconductor regions of the above embodiments are shown as either N-type or P-type, in other embodiments, the N-type regions can optionally be doped with phosphorous, arsenic and/or antimony, and the P-type regions can optionally be doped with boron, aluminum and/or gallium. Elements of one embodiment may be combined with other embodiments in addition to or in lieu of the elements of the other embodiments. Accordingly, the technology is not limited except as by the appended claims.

I/we claim:

1. A process for manufacturing a JFET device, comprising:
forming a gate region;
forming a channel region having a channel size;
forming a source region; and
forming a drain region, wherein the channel size is controlled by adjusting a layout width when forming the gate region.

2. The process of claim 1 wherein the source region, the drain region and the channel region are doped with a first doping type, and wherein the gate region is doped with a second doping type different than the first doping type.

3. The process of claim 2 wherein forming the drain region comprises forming a drain contact region at one side of the gate region, and wherein forming the source region comprises forming a source contact region at another side of the gate region, and further wherein the drain contact region and the source contact region are formed in one operation.

4. The process of claim 1 wherein forming the gate region and forming the channel region comprises:
forming an epitaxial layer of a first doping type on a semiconductor substrate;
placing a photoresist layer onto the epitaxial layer;
forming a gate opening with the layout width on the photoresist layer; and
implanting into the gate opening dopants of a second doping type and performing a thermal annealing process to form the gate region, wherein the channel region is formed under the gate region in the epitaxial layer.

5. The process of claim 4 wherein before placing the photoresist layer onto the epitaxial layer, the process further comprises doping into the epitaxial layer a first doping type.

6. The process of claim 1, wherein the layout width is adjusted with a negative relationship to the channel size.

7. The process of claim 1 wherein the layout width is adjusted with a negative relationship to a target threshold voltage.

8. The process of claim 1 wherein the layout width is adjusted with a positive relationship to a target drain-source resistance.

9. The process of claim 1 wherein forming the gate region and forming the channel region comprises:
forming the gate region of a first doping type on a substrate with a mask having the layout width;
forming an oxide layer above the gate region;
forming a well of a second doping type with the oxide layer as the mask; and
forming the channel region by performing thermal annealing to side diffuse the well under the gate region.

10. A semiconductor device, comprising a JFET device having a gate, a source, a drain, and a channel in a semiconductor substrate, wherein:
the drain, the source, and the channel are of a first doping type;
the gate is of a second doping type;
the channel is between the gate and the substrate vertically and between the source and the drain laterally; and
wherein a depth of the gate has a positive relationship with a width of the gate.

11. The semiconductor device of claim 10 further comprising a peripheral region, wherein the peripheral region comprises a doped well of a second doping type and the doped well has a second width and a second depth, wherein the width of the gate is longer than the second width while the depth of the gate is deeper than the second depth.

12. The semiconductor device of claim 10 further comprising a peripheral region, wherein the peripheral region comprises a doped well of a second doping type and the doped well has a second width and a second depth, and wherein the width of the gate is shorter than the second width while the depth of the gate is shallower than the second depth.

13. The semiconductor device of claim 12 wherein the gate and the doped well are fabricated with a single mask.

14. The semiconductor device of claim 10 wherein the JFET device is a first JFET device, and wherein the semiconductor device further comprises a second JFET device, wherein the first JFET device has a first drain-source resistance and a first gate width, and the second JFET device has a second drain-source resistance and a second gate width, and wherein the first drain-source resistance is lower than the second drain-source resistance while the first gate width is wider than the second gate width.

15. The semiconductor device of claim 14 wherein a threshold voltage of the first JFET device is lower than a threshold voltage of the second JFET device.

16. The semiconductor device of claim 14 wherein the gate depth of the first JFET device is deeper than the gate depth of the second JFET device.

17. A process of forming a JFET device, comprising:
forming a first well of a first doping type;
forming a gate region of a second doping type, wherein the gate region is a counter part of the first well;
forming a channel region of a first doping type, wherein the channel region has a channel size;
forming a source region of a first doping type;
forming a drain region of a first doping type; and
controlling the channel size by adjusting a layout width when forming the first well.

18. The process of claim 17 wherein forming the gate region comprises:
forming an oxide layer on a surface of the first well; and
implanting of a second doping type with the oxide layer as a mask.

19. The process of claim 18 wherein forming the channel region comprises performing thermal annealing to side diffuse the well under the gate region.

20. The process of claim 17 wherein a layout of the well is adjusted according to a target threshold voltage and/or a target current carrying capability of the JFET device.
